(19) United States
(12) Patent Application Publication
(10) Pub. No.: US 2026/0342332 A1
(43) Pub. Date: Oct. 29, 2026

(54) BJT Switch Assembly Self-Power Supply

(71) Applicant: IDEAL POWER INC., Austin, TX (US)

(72) Inventors: Ruiyang YU, Austin, TX (US); Seyed Milad TAYEBI, Austin, TX (US); Nicholas GLASCOCK-ILLESCAS, Austin, TX (US)

(73) Assignee: IDEAL POWER INC., Austin, TX (US)

(21) Appl. No.: 19/558,678

(22) Filed: Mar. 6, 2026

Related U.S. Application Data
(60) Provisional application No. 63/795,847, filed on Apr. 28, 2025.

(51) Int. Cl. H03K 17/66; H02M 1/088; H03K 17/567

(52) U.S. Cl. CPC H03K 17/665; H02M 1/088; H03K 17/567

(57) ABSTRACT

A switch assembly system includes a bidirectional switch configured to receive, via an input of the bidirectional switch, a DC input current and selectively supply, via an output of the bidirectional switch, a DC load current. A driver is coupled to a control input and the bidirectional switch and is configured to, responsive to assertion of the control input, control the bidirectional switch to conduct and supply the DC load current responsive to assertion of the control input, and, responsive to de-assertion of the control input, control the bidirectional switch to cease conduction of the DC load current. A power supply is coupled to an output of the bidirectional switch. The power supply is configured to supply the DC load current from the bidirectional switch, convert a portion of the DC load current to an AC input current, and supply, using the AC input current, power to the driver.

### CROSS-REFERENCE TO RELATED APPLICATIONS

This application claims the benefit of U.S. Provisional Application No. 63/795,847, filed on Apr. 28, 2025. The entire disclosure of the application referenced above is incorporated herein by reference.

### BACKGROUND

Switch assemblies may be used in various electrical switching applications to provide and interrupt flow of electrical current to electrical devices, loads, etc. As one example, switch assemblies may be implemented in solid state circuit breakers (SSCBs).

An example switch assembly may include a power semiconductor device configured to function as a bidirectional switch and a driver (e.g., a gate driver circuit) configured to control a conductive state of the bidirectional switch. A power semiconductor device is a semiconductor device that configured to handle and control high voltages and currents in electrical circuits. Power semiconductor devices are used in power electronics, which relates to the conversion, control, and conditioning of electric power, such as in control of industrial machinery and renewable energy systems.

In some examples, the power semiconductor device may include one or more double-sided double-base (DSDB) bipolar junction transistors (BJTs), which are junction transistors constructed with a base and collector-emitter on a first side of the bulk region, and a distinct and separate base and collector-emitter on a second side of the bulk region, opposite the first side. When configured by the driver, electrical current may selectively flow through the collector-emitters of the DSDB BJT in either direction, and thus such devices are considered bi-directional devices. For example, the driver is configured to provide voltage and current to switch the BJTs.

### SUMMARY

A switch assembly system includes a bidirectional switch configured to receive, via an input of the bidirectional switch, a direct current (DC) input current and selectively supply, via an output of the bidirectional switch, a DC load current. At least one driver is coupled to a control input and the bidirectional switch and is configured to, responsive to assertion of the control input, control the bidirectional switch to conduct and supply the DC load current responsive to assertion of the control input, and, responsive to de-assertion of the control input, control the bidirectional switch to cease conduction of the DC load current. A power supply is coupled to an output of the bidirectional switch. The power supply is configured to supply the DC load current from the bidirectional switch, convert at least a portion of the DC load current to an AC input current, and supply, using the AC input current, power to the at least one driver to power the at least one driver.

### BRIEF DESCRIPTION OF THE DRAWINGS

For a detailed description of example embodiments, reference will now be made to the accompanying drawings in which:

FIG. 1 shows an example switch assembly according to the principles of the present disclosure;

FIG. 2 shows an example bidirectional switch according to the principles of the present disclosure;

FIG. 3 shows a functional block diagram of an example switch assembly system 300 according to the principles of the present disclosure;

FIG. 4A shows a switch assembly system including an example implementation of a power supply according to the principles of the present disclosure;

FIG. 4B shows an example implementation of a power supply according to the principles of the present disclosure;

FIG. 4C shows another example implementation of a power supply according to the principles of the present disclosure;

FIG. 5 shows a block diagram of an example computing device configured to implement functions of the systems and methods of the present disclosure; and

FIG. 6 shows an example method of controlling or operating a switch assembly according to the principles of the present disclosure.

### DEFINITIONS

Various terms are used to refer to particular system components. Different companies may refer to a component by different names – this document does not intend to distinguish between components that differ in name but not function. In the following discussion and in the claims, the terms “including” and “comprising” are used in an open-ended fashion, and thus should be interpreted to mean “including, but not limited to… .” Also, the term “couple” or “couples” is intended to mean either an indirect or a direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” or “approximately” in reference to a recited parameter shall mean the recited parameter plus or minus ten percent (+/- 10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

“FET” shall mean a field effect transistor, such as a junction-gate FET (JFET) or metal-oxide-silicon FET (MOSFET).

“Closing” in reference to an electrically-controlled switch (e.g., a FET) shall mean making the electrically-controlled switch conductive. For example, closing a FET used as an electrically-controlled switch may mean driving the FET to the fully conductive state.

“Opening” in reference to an electrically-controlled switch (e.g., a FET) shall mean making the electrically-controlled switch non-conductive. Leakage current shall not negate the status of an electrically-controlled switch being non-conductive.

“DSDB-BJT” shall mean a double-sided double-base (DSDB) bipolar junction transistor (BJT) having base and collector-emitter on a first side of a drift region, and a distinct and separate base and collector-emitter on a second side of the drift region, opposite the first side. The drift region may be continuous, or the drift region may include an upper drift region associated with the upper base and upper collector-emitter, and a lower drift region associated with the lower base and lower collector-emitter.

“Collector-emitter” of a bipolar junction transistor shall mean a region of the bipolar junction transistor through which main load current flows. For purposes of this specification and claims, the designation as a collector-emitter is independent of the underlying device physics within the bipolar junction transistor. For example, for a double-sided double-base PNP transistor, the main load current may flow from an upper P-type region, through the bulk N-type drift region, and then out the lower P-type region, and when so used the upper P-type region and the lower P-type region are considered collector-emitters. However, in other cases, such as described in co-pending and commonly assigned U.S. App. 18/483,939 filed Oct. 10, 2023 and titled “Methods and Systems of Operating a PNP Bi-Directional Double-Base Bipolar Junction Transistor,” the main load current may flow from an upper N-type region, through the bulk N-type drift region, and then through the lower N-type region, and when so used the upper and lower N-type regions are considered collector-emitters.

“Base” of a bipolar junction transistor shall mean a region of the bipolar junction transistor through which control current flows, the control current distinct from the main load current. For purposes of this specification and claims, the designation as a base is independent of the underlying device physics within the bipolar junction transistor. For example, for a double-sided double-base PNP transistor, the control current may flow into an upper N-type region or a lower N-type region, and when so used the upper N-type region and the lower N-type region are considered bases. However, in other cases, such as described in co-pending and commonly assigned U.S. App. 18/483,939 noted above, the control current may flow into an upper P-type region or a lower P-type region, and when so used the upper and lower P-type regions are considered bases.

“Upper” in reference to component (e.g., upper collector-emitter, upper base) shall not be read to imply a location of the recited component with respect to gravity. Upper may be derived from location of the device in an example drawing.

“Lower” in reference to a component (e.g., upper collector-emitter, upper base) shall not be read to imply a location of the recited component with respect to gravity. Lower may be derived from location of the device in an example drawing.

The terms “input” and “output” when used as nouns refer to connections (e.g., electrical, software), and shall not be read as verbs requiring action. For example, a timer circuit may define a clock output. The example timer circuit may create or drive a clock signal on the clock output. In systems implemented directly in hardware (e.g., on a semiconductor substrate), these “inputs” and “outputs” define electrical connections. In systems implemented in software, these “inputs” and “outputs” define parameters read by or written by, respectively, the instructions implementing the function.

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

An example switch assembly may include a power semiconductor device configured to function as a bidirectional switch, which may be implemented using one or more DSDB BJTs. A driver, such as a gate driver circuit, is configured to provide voltage and current to switch the BJTs to selectively enable and interrupt flow of current through the switch assembly.

The driver requires input power to drive the bidirectional switch. For example, the driver may receive power from a dedicated power supply, from the electrical power being input to the switch assembly, from a controller or operational power source or supply, etc. In examples where the driver is powered using the power input to the switch assembly, a converter arranged upstream of the switch assembly may be used to convert the power from high power to low power suitable for the driver. In one example, the driver may be configured to operate with a voltage range of approximately 0.5-1.0 V (e.g., 0.7 V). Conversely, for high power applications (e.g., high power SSCB applications for DC current), an input voltage may be 400 V or greater. Accordingly, a converter may be used to convert the 400 V input voltage to the 0.7 V driver voltage, such as a 2- or 3-stage converter with one or more isolation elements. Circuitry required to perform such a conversion increases costs, control complexity, power consumption, and space requirements.

Switch assembly systems and methods according to the principles of the present disclosure implement a self-power, inline power supply configured to provide power to the driver using power (e.g., electrical current) output from the switch assembly as described below in more detail.

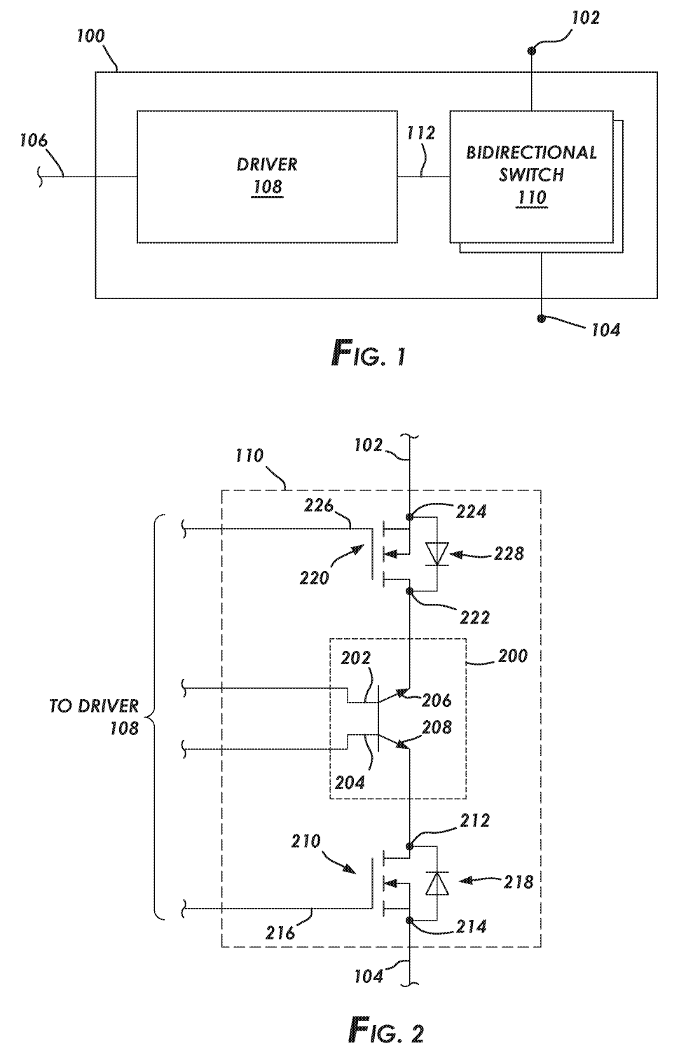

FIG. 1 shows an example switch assembly 100. In particular, the example switch assembly 100 defines an upper terminal 102, a lower terminal 104, and a control input or control terminal 106. Internally, the example switch assembly 100 includes a driver 108 and a bidirectional switch 110. The driver 108 defines the control terminal 106, and the driver 108 is coupled to the bidirectional switch 110, as shown by connections 112. The connections 112, though shown as a single connection, represent a plurality of electrical connections to the bidirectional switch 110 whose conductive state may vary. The driver 108 controls the conductive state of the bidirectional switch 110 by controlling the voltages/currents on the connections 112.

One example of the switch assembly 100 may include a single bidirectional switch 110. Another example switch assembly 100 may have two or more bidirectional switches 110, as illustrated in FIG. 1 by the “stacked” arrangement for the bidirectional switch 110. When multiple bidirectional switches 110 are present, the bidirectional switches 110 are electrically connected in parallel to share the main load current (forward or reverse). So as not to unduly complicate the specification, the discussion that follows assumes a single bidirectional switch 110. However, one having ordinary skill, and with the benefit of this disclosure, understands that the multiple bidirectional switches may be present depending on the designed current carrying capability of any specific switch assembly 100.

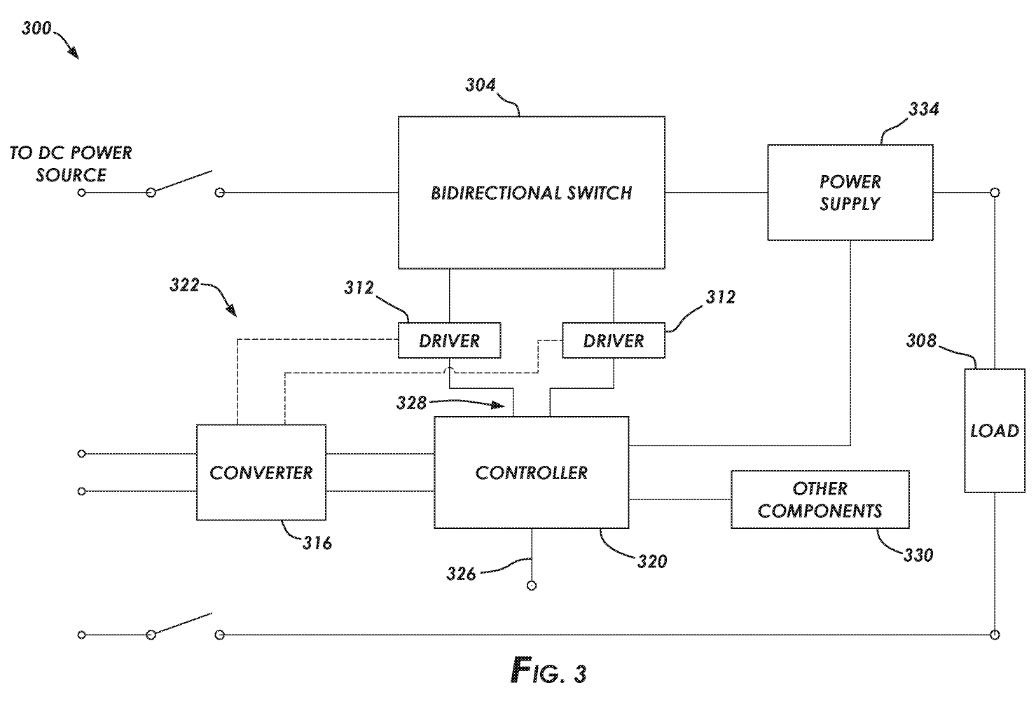

FIG. 2 shows a schematic of an example bidirectional switch 110. In particular, the example bidirectional switch 110 includes a DSDB-BJT 200. The example DSDB-BJT 200 defines an upper base 202, a lower base 204, an upper collector-emitter 206, and a lower collector-emitter 208. The example bidirectional switch 110 further includes a lower-main or lower cascode FET 210 that defines a drain 212 coupled to the lower collector-emitter 208, a source 214 coupled to the lower terminal 104, a gate 216 coupled to the driver 108, and a body diode 218. Finally, the example bidirectional switch 110 includes an upper-main or upper cascode FET 220 that defines a drain 222 coupled to the upper collector-emitter 206, a source 224 coupled to the upper terminal 102, a gate 226 coupled to the driver 108, and a body diode 228.

The driver 108 is coupled to the bidirectional switch 110 by a plurality of electrical connections. In the example of FIG. 2, the electrical connections to the driver 108 may comprise connections to: the gate 226 of the upper cascode FET 220; the upper collector-emitter 206; the upper base 202; the lower base 204; the lower collector-emitter 208; and the gate 216 of the lower cascode FET 210. The driver 108 controls states/modes of the bidirectional switch 110 by controlling the voltages/currents on the various connections. States of the bidirectional switch 110 include, but are not limited to, passive off, passive on, active on, alternative active on, pre-turn off, reverse recovery, and alternative reverse recovery states. Example control and operation of the bidirectional switch 110 and the various states are described in more detail in U.S. Pat. Application No. 18/583,188, filed on Feb. 21, 2024, the entire contents of which are incorporated herein by reference.

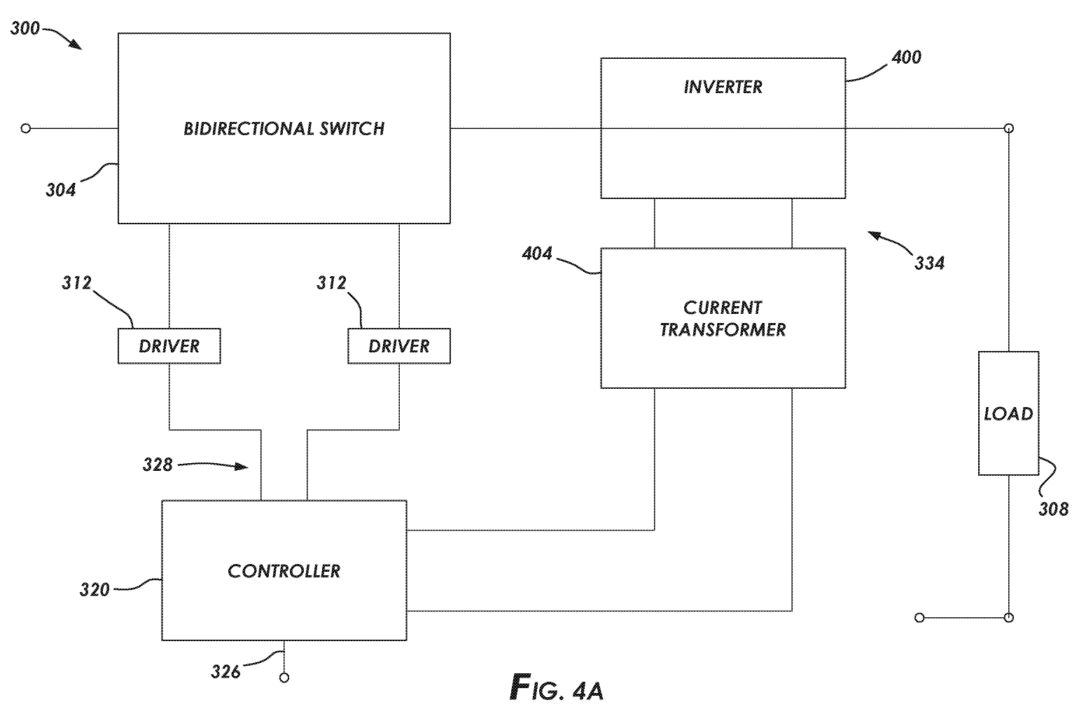

FIG. 3 shows a functional block diagram of an example switch assembly system 300 according to the principles of the present disclosure. The system 300 includes a switch assembly (shown, for example, as a bidirectional switch 304) configured to selectively enable and interrupt flow of current from a power source (e.g., a high power DC source) to a load 308. One or more drivers 312 control various states of the bidirectional switch 304 as described above.

The system 300 further includes a converter 316 and a controller 320. In some examples, the converter 316 may include one or more electrical isolators or isolation circuits, such as one or more transformers. In an example, the converter 316 receives switched or converted DC power (e.g., as AC power that is output by an inverter that receives DC power and converts the DC power to AC power). For example, the converter 316 is configured to convert voltage/current from a high power source (e.g., the same DC power source used to power the load 308) to power suitable for use by the controller 320. In some conventional examples, the converter 316 may be further configured to provide power to the drivers 312 (as indicated by dashed lines 322).

The controller 320 receives one or more control inputs 326 and provides one or more control outputs 328 to the drivers 312. The controller 320 is configured to control the drivers 312 to selectively enable and interrupt flow of current through the bidirectional switch 304 as described above. In various examples, the controller 320 may implement or be implemented as individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations thereof, configured to receive the inputs 326 and provide the outputs 328 to control the drivers 312 and the bidirectional switch 304.

Various devices within the switch assembly system 300 may use operational power. For example, the controller 320 may use a bus voltage and power to enable implementation of the various modes of operation of the bidirectional switch 304. Further, sources within system 300 may be implemented as individual voltage sources in the form of switching power converters, individual current sources also in the form of switching power converters, and so on. The switching power converters implementing the sources may use bus voltage and power. In order to provide operational power within the electrical domain of the system 300, the converter 316 is provided. External systems (not shown) may provide an AC signal to the converter 320 as described above (e.g., via an isolation transformer; not shown). In this manner, AC voltage/power can be provided to various components of the system 300 via a bus voltage V_{BUS} (e.g., 3.3V, 5V, 12V, etc.), including, but not limited to, the controller 320 and other components 330 (e.g., various sensors, fans, and other electrical components). In other examples, multiple converters (e.g., multiple isolation transformers) may be provided. Further still, a single isolation transformer with multiple secondary windings may be used.

As described above, the drivers require input power to drive the bidirectional switch 304. In various example switch assembly systems, the drivers 312 may receive power from a dedicated power supply, from the electrical power being input to the switch assembly (e.g., from the converter 316, as indicated by the dashed lines 322), from a controller or operational power source or supply, etc. Circuitry required to perform such a conversion increases costs, control complexity, power consumption, and space requirements. Accordingly, the switch assembly system 300 according to the present disclosure implements a self-power, inline power supply 334 configured to provide power to the drivers 312 using power output to the load 308 from the bidirectional switch 304 as described below in more detail.

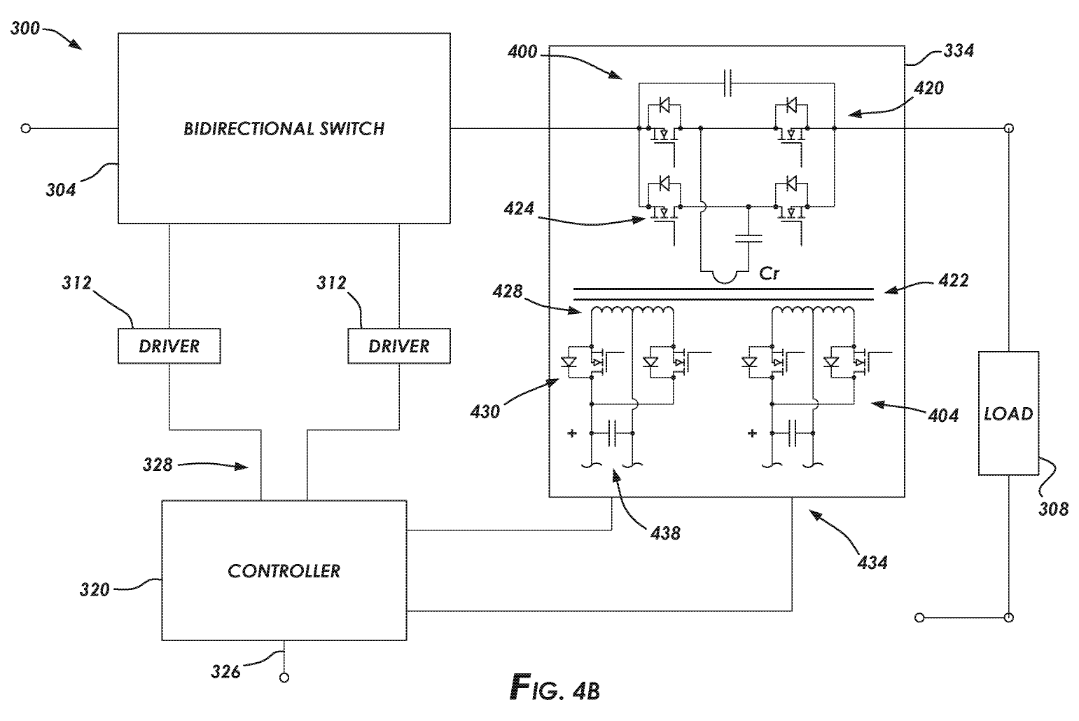

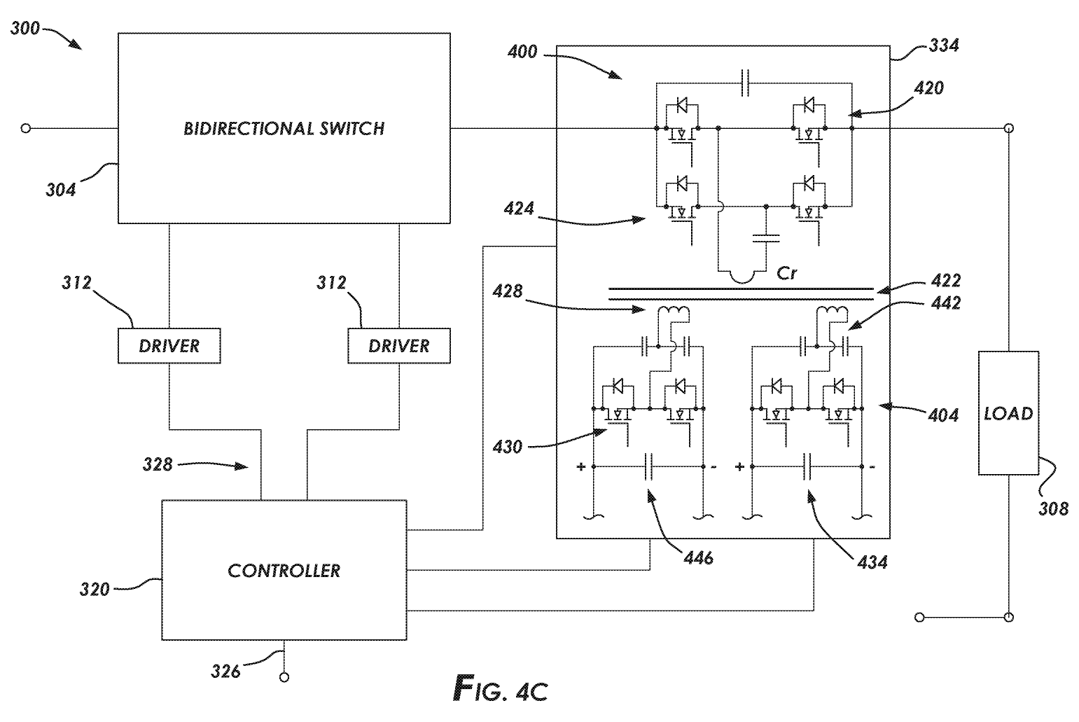

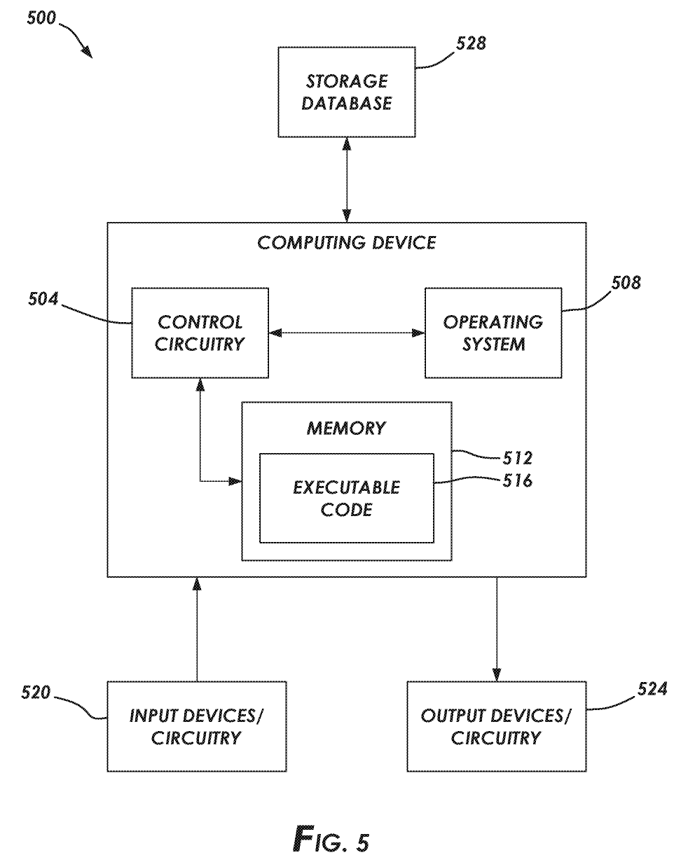

FIG. 4A shows the switch assembly system 300 including an example implementation of the power supply 334 according to the principles of the present disclosure. For example, the power supply 334 functions as a current transformer configured to receive current output (e.g., a DC “load current”) from the bidirectional switch 304 to the load 308 and convert and transform the current to a current suitable for providing power to the drivers 312 (e.g., to inject power into the bases of a switching transistor (e.g., the upper base 202 and lower base 204 of the DSDB-BJT 200) of the bidirectional switch 304.

As shown, the power supply 334 includes an inverter 400 and a current transformer 404. The inverter 400 is configured to receive the DC load current and both (i) provide the DC load current (e.g., unmodified) to the load 308 and (ii) convert the DC load current to an AC current and provide the AC current to the current transformer 404. For example, the inverter 400 may simply functions as a pass-through for the DC load current provided to the load 308. Conversely, the inverter 400 includes inverter circuitry (e.g., a switching network, full-bridge circuit, half-bridge circuit, etc.) configured to convert the DC load current to the AC current.

FIG. 4B shows one example implementation of the power supply 334 according to the principles of the present disclosure in more detail. In this example, the inverter 400 includes, as example inverter circuitry, a bridge circuit 420 configured to flow DC current to the load 308 while also selectively providing AC current to a primary winding 422 of the current transformer 404. For example, the bridge circuit 420 includes a switching network of switches (e.g., transistors 424), which may be selectively switched ON or OFF (e.g., by the controller 320) to control direction of flow of current through the inverter 400. The transistors 424 may be controlled such that the DC current is always (e.g., when output by the bidirectional switch 304) provided by the inverter 400 to the load 308 in a same direction but alternates direction through the primary winding of the current transformer 404. In this manner, the inverter 400 provides AC current to the current transformer 404. In an example, the transistors 424 are lower power (e.g., approximately 20 v or less) transistors. In some examples, the inverter 400 provides the AC current via a resonant circuit such as capacitor (Cr), a resistor-capacitor RC network, an inductor-capacitor (LC) network, an LCC resonance tank, etc.

The current transformer 404 may include two secondary windings 428 and respective switches/switching circuitry (e.g., transistors) 430 configured to convert/decrease the AC current (e.g., from a first, higher current to a second, lower current) and selectively provide the converted AC current to the respective drivers 312 (e.g., via the controller 320). For example, the switching circuitry 430 is responsive to control signals from the controller 320. In this manner, the controller 320 may be configured to control the switching circuitry 430 to selectively provide suitable AC current to the drivers 312. In this example, each of the secondary windings 428 is coupled, at respective ends, to a respective pair of the switches 430 (e.g., the secondary windings 428 are coupled in series with the respective pairs of switches 430). For example, sources of the switches 430 are coupled to the ends of the secondary windings 428, drains of the switches 430 are coupled (and provide current to) outputs 434 of the power supply 334, and gates of the switches 430 receive respective control signals (e.g., from the controller 320). In some examples, respective capacitors 438 are coupled between the respective drains of the switches 430 and respective center taps of the secondary windings 428, as shown.

FIG. 4C shows another example implementation of the power supply 334 according to the principles of the present disclosure. In this example, each of the secondary windings 428 is coupled, at a first end, to a node between the respective pair of switches 430 and, at a second end, to a node between a pair of capacitors 442 arranged in parallel to the respective pair of switches 430. Accordingly, a source of first one of the pair of switches 430 and a drain of a second one of the pair of switches 430 is coupled to the first end of the secondary winding 428, a drain of the first one of the pair of switches 430 is coupled to the second end of the secondary winding 428 via a first capacitor of the pair of capacitors 442, and a source of the second one of the pair of switches 430 is coupled to the first end of the secondary winding via a second capacitor of the pair of capacitors 442, as shown. Gates of the switches 430 receive respective control signals (e.g., from the controller 320). In some examples, respective capacitors 446 are coupled in parallel with the pairs of switches 420 (e.g., between the drain of the first one of the pair of switches 430 and the source of the second one of the pair of switches 430).

The examples shown in FIGS. 4B and 4C are only two example implementations of the power supply 334, inverter 400, and current transformer 404 shown more generally in FIG. 4A, and other examples of the inverter 400 and the current transformer 404 may be implemented using the principles of the present disclosure. Generally, the switch assembly system 300 according to the present disclosure includes a self-power, inline power supply (e.g., the power supply 334) that is coupled at an output of the bidirectional switch 304 and is configured to provide both the high power, DC current to the load 308 and a relatively low power, AC current to power the drivers 312.

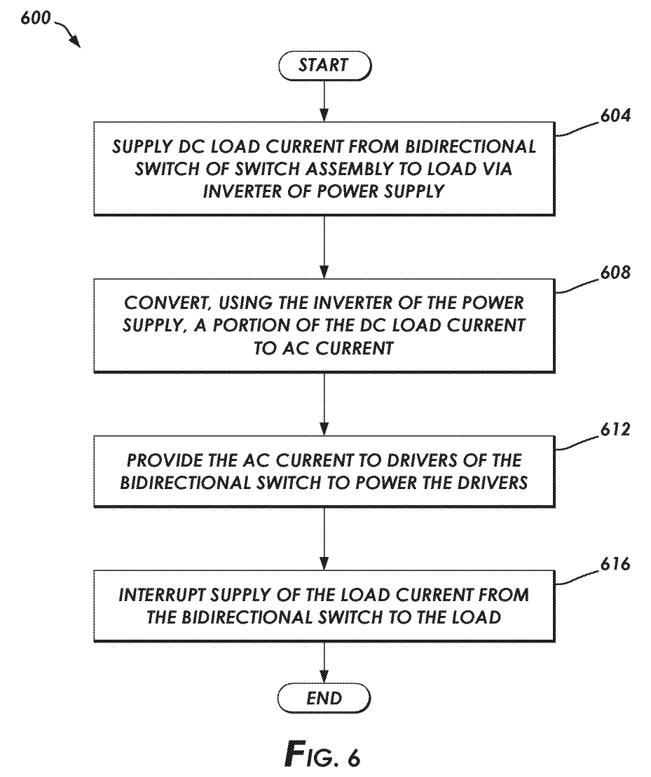

FIG. 5 shows a block diagram of an example computing device 500 configured to implement functions of the systems and methods described herein according to the present disclosure. For example, one or more of the computing devices 500 may implement or be implemented by the one or more components of the system 300, such as the controller 320. Systems described herein may implement a single computing device, a plurality of computing devices, etc., configured to individually and/or collectively perform functions related to the systems and methods of the present disclosure.

The computing device 500 may include control circuitry 504 that may be, for example, one or more processors or processing devices, a central processing unit processor, an integrated circuit or any suitable computing or computational device, an operating system 508, memory 512, executable code 516, input devices or circuitry 520, and output devices or circuitry 524. The control circuitry 504 (or one or more controllers or processors, possibly across multiple units or devices) may be configured to implement functions of the systems and methods described herein. More than one of the computing devices 500 may be included in, and one or more of the computing devices 500 may act as the components of, a system according to embodiments of the disclosure. Various components of the computing device 500 may be implemented with same or different circuitry, same or different processors or processing devices, etc.

The operating system 508 may be or may include any code segment (e.g., one similar to the executable code 516 described herein) configured and/or configured to perform tasks involving coordination, scheduling, arbitration, supervising, controlling or otherwise managing operation of the control circuitry 504 (e.g., scheduling execution of software programs or tasks or enabling software programs or other hardware modules or units to communicate). The operating system 508 may be a commercial operating system. The operating system 508 may be an optional component (e.g., in some embodiments, a system may include a computing device that does not require or include the operating system 508). For example, a computer system may be, or may include, a microcontroller, an application specific circuit (ASIC), a field programmable array (FPGA), network controller (e.g., CAN bus controller), associated transceiver, system on a chip (SOC), and/or any combination thereof that may be used without an operating system.

The memory 512 may be or may include, for example, Random Access Memory (RAM), read only memory (ROM), Dynamic RAM (DRAM), Synchronous DRAM (SD-RAM), a double data rate (DDR) memory chip, Flash memory, volatile memory, non-volatile memory, cache memory, a buffer, a short-term memory unit, a long-term memory unit, or other suitable memory units or storage units. The memory 512 may be or may include a plurality of memory units, which may correspond to same or different types of memory or memory circuitry. The memory 512 may be a computer or processor non-transitory readable medium, or a computer non-transitory storage medium, e.g., RAM.

The executable code 516 may be any executable code, e.g., an application, a program, a process, task, or script. The executable code 516 may be executed by the control circuitry 504, possibly under control of the operating system 508. Although, for the sake of clarity, a single item of the executable code 516 is shown, a system according to some embodiments of the disclosure may include a plurality of executable code segments similar to the executable code 516 that may be loaded into the memory 512 and cause the control circuitry 504 to carry out methods described herein. Where applicable, the terms “process” and “executable code” may be used interchangeably herein. For example, verification, validation and/or authentication of a process may mean verification, validation and/or authentication of executable code.

In some examples, the memory 512 may include non-volatile memory having the storage capacity of a storage system. In other examples, the computing device 500 may include or communicate with a storage system and/or database. Such a storage system may include, for example, flash memory, memory that is internal to, or embedded in, a micro controller or chip, a hard disk drive, a solid-state drive, a CD-Recordable (CD-R) drive, a Blu-ray disk (BD), a universal serial bus (USB) device or other suitable removable and/or fixed storage unit. Content may be stored in the storage system and loaded from the storage system into the memory 512 where it may be processed by the control circuitry 504.

The input circuitry 520 may be or may include any suitable input devices, components, or systems, e.g., physical sensors such as accelerometers, thermometers, microphones, analog to digital converters, etc., a detachable keyboard or keypad, a mouse, etc. The output circuitry 524 may include one or more (possibly detachable) displays or monitors, motors, servo motors, speakers and/or any other suitable output devices. Any applicable input/output (I/O) devices may be connected to the control circuitry 504. For example, a wired or wireless network interface card (NIC), a universal serial bus (USB) device, or external storage device may be included in the input circuitry 520 and/or the output circuitry 524. It will be recognized that any suitable number of input devices and output devices may be operatively connected to the control circuitry 504. For example, the input circuitry 520 and the output circuitry 524 may be used by a technician or engineer in order to connect to the control circuitry 504, update software, and the like.

Embodiments may include an article such as a computer or processor non-transitory readable medium, or a computer or processor non-transitory storage medium, such as for example memory, a disk drive, or USB flash memory, encoding, including or storing instructions (e.g., computer-executable instructions, which, when executed by a processor or controller, carry out methods disclosed herein), a storage medium such as the memory 512, computer-executable instructions such as the executable code 516, and a controller such as the control circuitry 504.

The storage medium may include, but is not limited to, any type of disk including magneto-optical disks, semiconductor devices such as read-only memories (ROMs), random access memories (RAMs), such as a dynamic RAM (DRAM), erasable programmable read-only memories (EPROMs), flash memories, electrically erasable programmable read-only memories (EEPROMs), magnetic or optical cards, or any type of media suitable for storing electronic instructions, including programmable storage devices.

Embodiments of the disclosure may include components such as, but not limited to, a plurality of central processing units (CPU) or any other suitable multi-purpose or specific processors or controllers (e.g., controllers similar to the control circuitry 504), a plurality of input units, a plurality of output units, a plurality of memory units, and a plurality of storage units, etc. A system may additionally include other suitable hardware components and/or software components. In some embodiments, a system may include or may be, for example, a personal computer, a desktop computer, a mobile computer, a laptop computer, a notebook computer, a terminal, a workstation, a server computer, a Personal Digital Assistant (PDA) device, a tablet computer, a network device, or any other suitable computing device.

In some embodiments, a system may include or may be, for example, a plurality of components that include a respective plurality of central processing units, e.g., a plurality of CPUs as described, a plurality of CPUs embedded in an on-board system or network, a plurality of chips, FPGAs or SOCs, microprocessors, transceivers, microcontrollers, a plurality of computer or network devices, any other suitable computing device, and/or any combination thereof. For example, a system as described herein may include one or more devices such as the control circuitry 504.

The computing device 500 may include and/or communicate with one or more storage devices or databases 528. For example, the storage database 528 may correspond to a storage device (e.g., a semiconductor storage device, such as a solid-state drive (SSD)) of the computing device 500, a remote storage device or database, a cloud computing system, etc. The storage database 528 may store data accessible by one or more components of the systems described herein.

In some examples, the computing device 500 may implement an artificial intelligence (AI) engine configured to execute one or more AI or machine learning (ML) models, etc. trained using data (“training data”) obtained during operation. Various components of the training data, an AI engine, ML models, etc. may be stored within the computing device 500 or external to the computing device 500 (e.g., in a remote server, a cloud computing system, etc.).

FIG. 6 shows an example method 600 of controlling/operating a switch assembly according to the principles of the present disclosure. For example, portions of the method 600 may be performed by one or more computing devices, processors or processing devices, etc., such as the controller 320, the computing device 500, and so on. Functions or steps of the method 600 may be performed by controlling various circuitry or circuity components, responsive to control signals, of the systems described herein. For example, the method 600 may be performed by selectively providing various voltages, currents, control signals, etc. to respective components of the switch assembly system 300.

At 604, the method 600 includes conducting/supplying a load current (e.g., a forward load current, such as a high power DC current) from bidirectional switch of a switch assembly to a load. For example, conducting the load current may include controlling one or more switches (e.g., DSDB-BJTs) of the bidirectional switch using respective control signals provided by a controller to respective drivers of the switches. In an example, the load current is provided to the load via a power supply coupled to an output of the bidirectional switch such that the load current flows from the bidirectional switch, through an inverter of the power supply, to the load.

At 608, the method 600 includes converting, using the inverter of the power supply, at least a portion of the load current from DC current to AC current. For example, converting the load current to AC current may include selectively operating switches of the inverter (e.g., using control signals provided by the controller) to cause current to flow in alternating directions through a primary winding of a current transformer.

At 612, the method 600 includes providing the AC current to the drivers of the bidirectional switch (i.e., to power the drivers). For example, providing the AC current to the drivers may include selectively operating switches (e.g., using control signals provided by the controller) coupled to an output side of the current transformer to supply current (e.g., AC current) from secondary windings of the current transformer to the drivers. In some examples, the current may be provided directly to the drivers. In other examples, the current may be provided to the controller, which is configured to distribute current power to the drivers and/or other components of the switch assembly system. In some examples, the controller may be configured to control the switches to provide/supply the current to the drivers at a same time that the load current is provided to the load (i.e., when the switches of the bidirectional switch and/or the inverter are controlled to supply the load current to the load). Conversely, the controller may be configured to control the switches to interrupt supply of current from the current transformer to the drivers when the load current is not provided to the load (i.e., when the switches of the bidirectional switch and/or the inverter are controlled to interrupt supply of the load current to the load).

At 616, the method 600 includes stopping/interrupting the supply of the load current from the bidirectional switch to the load. For example, interrupting the supply of the load current may include controlling the one or more switches of the bidirectional switch using respective control signals provided by the controller to the respective drivers of the switches.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A switch assembly system, comprising:
a bidirectional switch configured to receive, via an input of the bidirectional switch, a direct current (DC) input current and selectively supply, via an output of the bidirectional switch, a DC load current;
at least one driver coupled to a control input and the bidirectional switch, wherein the at least one driver is configured to, responsive to assertion of the control input, control the bidirectional switch to conduct and supply the DC load current responsive to assertion of the control input, and, responsive to de-assertion of the control input, control the bidirectional switch to cease conduction of the DC load current; and
a power supply coupled to an output of the bidirectional switch, wherein the power supply is configured to
supply the DC load current from the bidirectional switch,
convert at least a portion of the DC load current to an alternating current (AC) input current, and
supply, using the AC input current, power to the at least one driver to power the at least one driver.

2. The switch assembly system of claim 1, wherein the bidirectional switch includes a double-sided double-base bipolar junction transistor (DSDB-BJT) defining an upper base, an upper collector-emitter, a lower base, and a lower collector-emitter, and wherein the at least one driver is coupled to the upper base and the lower base of the DSDB-BJT.

3. The switch assembly system of claim 2, wherein the bidirectional switch further includes:
an upper-main FET defining a first lead coupled to an upper terminal of the bidirectional switch, a second lead coupled to the upper collector-emitter, and a gate; and
a lower-main FET defining a first lead coupled to the lower collector-emitter, a second lead coupled to a lower terminal of the bidirectional switch, and a gate,
wherein the at least one driver is further coupled to the gate of the upper-main FET, the gate of the lower-main FET.

4. The switch assembly system of claim 1, wherein the power supply includes an inverter configured to receive the DC load current, supply the DC load current to a load, and convert the portion of the DC load current to the AC input current.

5. The switch assembly system of claim 4, wherein the inverter includes a switching network configured to converter the portion of the DC load current to the AC input current.

6. The switch assembly system of claim 5, wherein the switching network includes at least one of a half-bridge circuit and a full-bridge circuit.

7. The switch assembly system of claim 5, wherein the switching network includes a plurality of switches responsive to respective control signals.

8. The switch assembly system of claim 4, wherein the power supply includes a current transformer coupled to the inverter to receive the AC input current.

9. The switch assembly system of claim 8, wherein the current transformer is configured to convert the AC input current to a converted AC input current and supply the power to the at least one driver using the converted AC input current.

10. The switch assembly system of claim 9, wherein the at least one driver includes a first driver and a second driver, and wherein the current transformer is configured to separately supply the power to the first driver and the second driver.

11. The switch assembly system of claim 10, wherein the current transformer includes:
a primary winding configured to receive the portion of the DC load current; and
first and second secondary windings respectively configured to supply the power to the first driver and the second driver.

12. The switch assembly system of claim 1, further comprising a controller coupled to the power supply and the at least one driver, wherein the controller is configured to (i) provide respective control signals to the power supply and the at least one driver and (ii) supply the power from the power supply to the at least one driver.

13. A method of operating a switch assembly, the method comprising:
receiving, at a bidirectional switch a direct current (DC) input current;
selectively supplying, via an output of the bidirectional switch, a DC load current;
using at least one driver responsive to assertion of a control input, control the bidirectional switch to conduct and supply the DC load current and, responsive to de-assertion of the control input, control the bidirectional switch to cease conduction of the DC load current;
receiving, at a power supply coupled to an output of the bidirectional switch, the DC load current; and
using the power supply, converting at least a portion of the DC load current to an alternating current (AC) input current and supplying, using the AC input current, power to the at least one driver to power the at least one driver.

14. The method of claim 13, wherein the bidirectional switch includes a double-sided double-base bipolar junction transistor (DSDB-BJT) defining an upper base, an upper collector-emitter, a lower base, and a lower collector-emitter, and wherein the at least one driver is coupled to the upper base and the lower base of the DSDB-BJT.

15. The method of claim 14, wherein the bidirectional switch further includes:
an upper-main FET defining a first lead coupled to an upper terminal of the bidirectional switch, a second lead coupled to the upper collector-emitter, and a gate; and
a lower-main FET defining a first lead coupled to the lower collector-emitter, a second lead coupled to a lower terminal of the bidirectional switch, and a gate,
wherein the at least one driver is further coupled to the gate of the upper-main FET, the gate of the lower-main FET.

16. The method of claim 13, wherein the power supply includes an inverter configured to receive the DC load current, supply the DC load current to a load, and convert the portion of the DC load current to the AC input current.

17. The method of claim 16, wherein the inverter includes a switching network configured to converter the portion of the DC load current to the AC input current, and wherein the switching network includes a plurality of switches responsive to respective control signals.

18. The method of claim 16, wherein the power supply includes a current transformer coupled to the inverter to receive the AC input current, and wherein the current transformer is configured to convert the AC input current to a converted AC input current and supply the power to the at least one driver using the converted AC input current.

19. The method of claim 18, wherein the at least one driver includes a first driver and a second driver, and wherein the current transformer is configured to separately supply the power to the first driver and the second driver, and wherein the current transformer includes:
a primary winding configured to receive the portion of the DC load current; and
first and second secondary windings respectively configured to supply the power to the first driver and the second driver.

20. The method of claim 13, further comprising, using a controller coupled to the power supply and the at least one driver, (i) providing respective control signals to the power supply and the at least one driver and (ii) supplying the power from the power supply to the at least one driver.
